(19) United States
(12) Patent Application Publication
(10) Pub. No.: US 2025/0315586 A1
(43) Pub. Date: Oct. 9, 2025

(54) DEEP TRENCH CAPACITOR LAYOUT

(71) Applicant: UNITED MICROELECTRONICS CORP., Hsin-Chu City (TW)

(72) Inventors: Chih-Kai Hsu, Tainan City (TW); Chang-Chien Wong, Tainan City (TW); Yu-Hsiang Lin, New Taipei City (TW); Chun-Tsen Lu, Tainan City (TW)

(73) Assignee: UNITED MICROELECTRONICS CORP., Hsin-Chu City (TW)

(21) Appl. No.: 18/663,125

(22) Filed: May 14, 2024

(30) Foreign Application Priority Data
Apr. 9, 2024 (TW) 113113081

(51) Int. Cl. G06F 30/392

(52) U.S. Cl. CPC G06F 30/392

(57) ABSTRACT

A deep trench capacitor (DTC) layout includes a first electrode layer on a substrate, a second electrode layer on the first electrode layer, a third electrode layer on the second electrode layer, and a fourth electrode layer on the third electrode layer. Preferably, the first electrode layer and the second electrode layer have different shapes in a top view and the second electrode layer and the third electrode layer have different shapes in a top view.

### BACKGROUND OF THE INVENTION

### 1. Field of the Invention

The invention relates to a deep trench capacitor (DTC) layout, and more particularly to a layout having electrode layers with different shapes under top view perspective.

### 2. Description of the Prior Art

Capacitors are important components in memory, logic and analog circuits. Due to the limitation of capacitance per unit area, capacitors always occupy a considerable chip area in a whole circuit layout. As integrated circuitry density has increased, the available die area for capacitors is decreasing. The decreased capacitor area in a denser circuit makes it more difficult to include capacitors having sufficiently high capacitance. Therefore, there remains a need for structures and methods that can increase capacitance for a fixed capacitor area on a chip.

### SUMMARY OF THE INVENTION

According to an embodiment of the present invention, a deep trench capacitor (DTC) layout includes a first electrode layer on a substrate, a second electrode layer on the first electrode layer, a third electrode layer on the second electrode layer, and a fourth electrode layer on the third electrode layer. Preferably, the first electrode layer and the second electrode layer have different shapes in a top view and the second electrode layer and the third electrode layer have different shapes in a top view.

According to another aspect of the present invention, a deep trench capacitor (DTC) layout includes a DTC cell comprising DTC patterns on a substrate and via conductors overlapping the DTC cell. Preferably, the via conductors include a cross shape in a top view.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a perspective view of a DTC and layout thereof according to an embodiment of the present invention.

FIGS. 2-3 illustrate perspective views of a DTC and layout thereof according to an embodiment of the present invention.

FIG. 4 illustrates a layout of an array constituted by grouping a plurality of DTC layout patterns shown in FIG. 3.

FIG. 5 illustrates a perspective view of a DTC and layout thereof according to an embodiment of the present invention.

FIG. 6 illustrates a layout of an array constituted by grouping a plurality of DTC layout patterns shown in FIG. 5.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

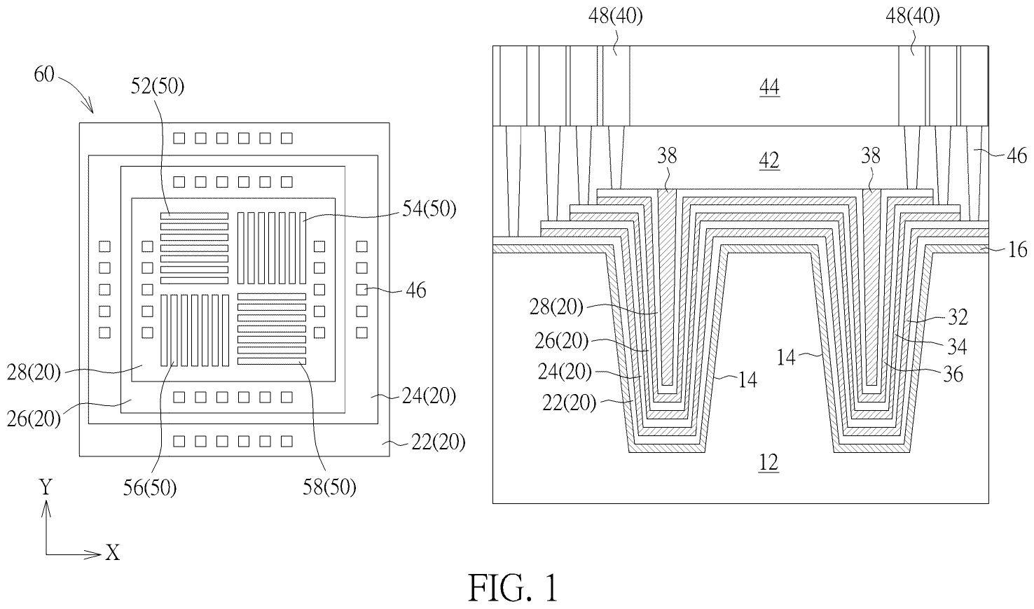

Referring to FIG. 1, FIG. 1 illustrates a perspective view of a DTC and layout thereof, in which the left portion of FIG. 1 illustrates a top view of the layout of the deep trench capacitor and right portion of FIG. 1 illustrates a cross-section view of the deep trench capacitor. As shown on the right portion of FIG. 1, a substrate 12 such as a semiconductor substrate or silicon substrate is provided and then a photo-etching process is conducted to remove part of the substrate 12 for forming one or more deep trenches 14 in the substrate 12. It should be noted that even though two deep trenches are formed in the substrate 12 in this embodiment, according to other embodiment of the present invention, it would also be desirable to form a single deep trench or more than two deep trenches in the substrate 12, which are all within the scope of the present invention.

Next, a liner 16 is conformally formed on the substrate 12, in which the liner 16 is disposed on the bottom surface of the deep trenches 14, sidewalls of the deep trenches 14, and surface of the substrate 12 adjacent to two sides of the deep trenches 14. According to an embodiment of the present invention, the liner 16 could include dielectric material such as silicon oxide or silicon nitride and the formation of the liner 16 could include but not limited to for example thermal oxidation process, thermal nitridation process, or chemical vapor deposition (CVD) process.

Next, a plurality of electrode layers 20 and dielectric layers 32, 34, 36, 38 are formed on the liner 16. For instance, four electrode layers 20 including a first electrode layer 22, a second electrode layer 24, a third electrode layer 26, and a fourth electrode layer 28 and four dielectric layers 32, 34, 36, 38 are stacked alternately from bottom to top on the liner 16. Next, a plurality of photo-etching processes are conducted to pattern the electrode layers 20 and dielectric layers 32, 34, 36, 38 as the patterned electrode layers 20 and dielectric layers 32, 34, 36, 38 are stacked alternately on the liner 16, the areas of the electrode layers 20 and the dielectric layers 32, 34, 36, 38 preferably decrease from bottom to top, and the electrode layers 20 and dielectric layers 32, 34, 36, 38 deposited into the deep trenches 14 on right portion of FIG. 1 preferably constitute four sets of deep trench capacitor patterns 52, 54, 56, 58 extending either toward X-direction or Y-direction on left portion of FIG. 1.

Specifically, it would be desirable to conduct a CVD process or a physical vapor deposition (PVD) process to form the first electrode layer 22 on the liner 16, forming the dielectric layer 32 and the second electrode layer 24 on the first electrode layer 22, conduct a first photo-etching process to remove part of the second electrode layer 24 and part of the dielectric layer 32, form the dielectric layer 34 and the third electrode layer 26 on the second electrode layer 24, conduct a second photo-etching process to remove part of the third electrode layer 26 and part of the dielectric layer 34, form the dielectric layer 36, the fourth electrode layer 28, and another dielectric layer 38 on the third electrode layer 26 and filling the deep trenches 14, and then conduct a third photo-etching process along with a planarizing process such as a chemical mechanical polishing (CMP) process to remove part of the dielectric layer 38, part of the fourth electrode layer 28, and part of the dielectric layer 36.

In this embodiment, the electrode layers 28 could include polysilicon, metals, conductive metal alloys or combination thereof, in which the metals could include tungsten (W), aluminum (Al), copper (Cu), or cobalt (Co) and conductive metal alloys could include titanium nitride (TiN), titanium silicide (TiSi₂), cobalt silicide (CoSi₂), nickel silicide (NiSi), or tungsten silicide (WSi₂).

The dielectric layers 32, 34, 36, 38 could include silicon oxide, silicon nitride, titanium oxide (TiO₂), aluminum oxide (Al₂O₃), zirconium oxide (ZrO₂), high-k dielectric layer. Preferably, the high-k dielectric layer is selected from dielectric materials having dielectric constant (k value) larger than 4. For instance, the high-k dielectric layer may be selected from hafnium oxide (HfO₂), hafnium silicon oxide (HfSiO₄), hafnium silicon oxynitride (HfSiON), aluminum oxide (A1₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

Next, one or more dielectric layers 42, 44 are formed to cover the electrode layers 20 and dielectric layers 32, 34, 36, 38, a photo-etching process is conducted to remove part of the dielectric layers 44, 42, for forming contact holes (not shown) exposing the electrode layers 20, metal or conductive materials are formed into the contact holes along with planarizing processes to form VO pickups made of via conductors 46 and metal interconnections 40 such as first level metal interconnection (M1) made of trench conductors 48, and a stop layer (not shown) could selectively formed on the metal interconnections 40 thereafter. In this embodiment, each of the via conductors 46 are conducted to the four electrodes 20 respectively, in which the odd number electrode layers 20 are connected to positive voltages while even number electrode layers 20 are connected to negative voltages. For instance, the first electrode layer 22 and the third electrode layer 26 are connected to positive voltages through the via conductors 46 while the second electrode layer 24 and the fourth electrode layer 28 are connected to negative voltages through the via conductors 46.

In this embodiment, the dielectric layers 42, 44 could include silicon oxide or ultra low-k (ULK) dielectric layers such as porous dielectric material including but not limited to for example silicon oxycarbide (SiOC) or carbon doped silicon oxide (SiOCH), the metal interconnections including the via conductors 46 and trench conductors 48 preferably include copper, and the stop layer preferably includes nitrogen doped carbide (NDC), silicon nitride, silicon carbon nitride (SiCN), or combination thereof.

As shown on the left portion of FIG. 1, the DTC layout preferably includes a DTC cell 60 having a plurality of DTC patterns 50 disposed on the substrate 12 and a plurality of via conductors 46 overlapping the DTC cell 60, in which each of the DTC patterns 50 is made of the aforementioned alternately stacked four electrode layers 20 and four dielectric layers 32, 34, 36, 38 as the via conductors 46 are evenly distributed on the electrode layers 20.

Specifically, the DTC patterns 50 include four sets of DTC patterns extending along the X-direction or Y-direction, in which the first DTC pattern 52 on top left corner includes a plurality of electrode layers 20 extending along a first direction such as X-direction, the second DTC pattern 54 on top right corner includes a plurality of electrode layers 20 extending along a second direction such as Y-direction, the third DTC pattern 56 on bottom left corner includes a plurality of electrode layers 20 extending along the second direction such as Y-direction, and the fourth DTC pattern 58 on bottom right corner includes a plurality of electrode layers 20 extending along the first direction such as X-direction. In other words, the first DTC pattern 52 and the fourth DTC pattern 58 are disposed diagonally while the second DTC pattern 54 and the third DTC pattern 56 are disposed diagonally.

In this embodiment, the electrode layers 20 under a top view perspective preferably have same shapes such as all having rectangular or square shapes while the area of the electrode layers 20 preferably decrease from top to bottom. For instance, the area of the bottommost layer or the first electrode layer 22 is greater than the area of the second electrode layer 24, the area of the second electrode layer 24 is greater than the area of the third electrode layer 26, and the area of the third electrode layer 26 is greater than the area of the fourth electrode layer 28. The via conductors 46 on the other hand are evenly distributed extending along X-direction or Y-direction adjacent to two sides of the electrode layers 20. For instance, the via conductors 46 are extending along X-direction on lower portion and upper portion of the first electrode layer 22, extending along Y-direction on left portion and right portion of the second electrode layer 24, extending along X-direction on lower portion and upper portion of the third electrode layer 26, and extending along Y-direction on left portion and right portion of the fourth electrode layer 28.

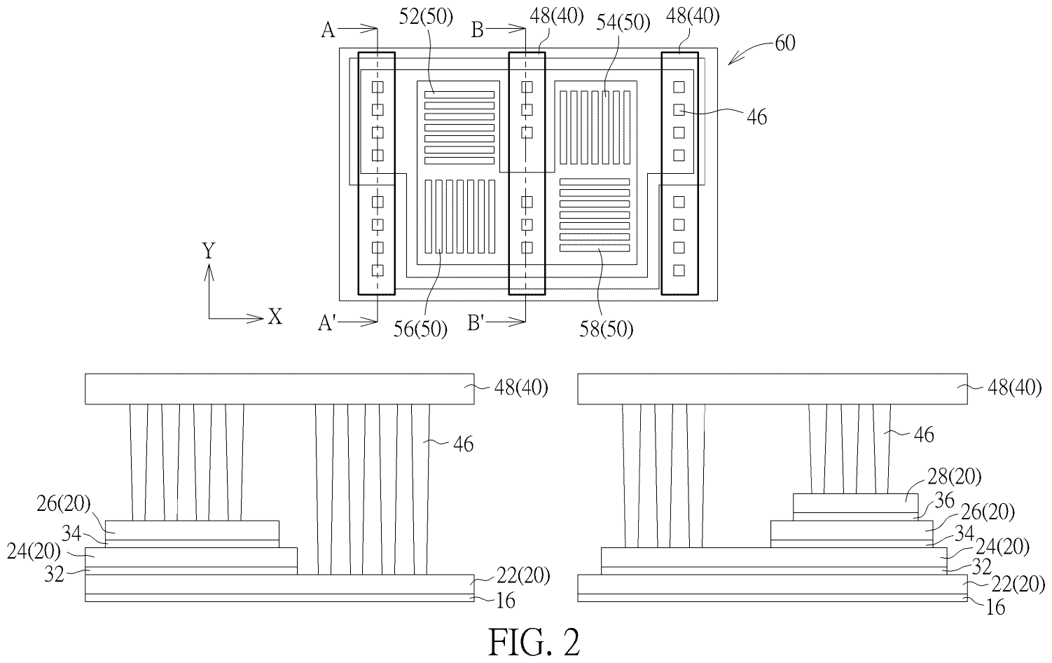

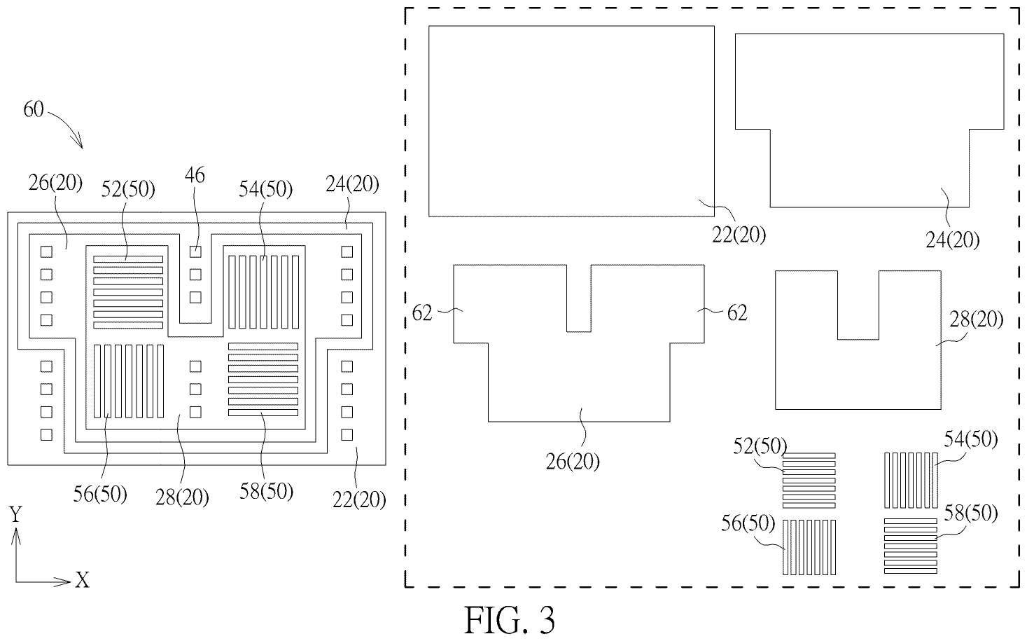

Referring to FIGS. 2-3, FIGS. 2-3 illustrate perspective views of a DTC and layout thereof according to an embodiment of the present invention, in which the top portion of FIG. 2 illustrates a top view of the DTC layout, the bottom left portion of FIG. 2 illustrates a cross-section of the DTC taken along the sectional line AA′ of the top portion, the bottom right portion of FIG. 2 illustrates a cross-section of the DTC taken along the sectional line BB′ of the top portion, the left portion of FIG. 3 illustrates a top view of the DTC layout, and the right portion of FIG. 3 illustrates a top view of the four electrode layers 20 from the DTC. As shown on the top portion of FIG. 2, the DTC layout includes a DTC cell 60 having a plurality of DTC patterns 50 disposed on the substrate 12 and a plurality of via conductors 46 overlapping the DTC cell 60.

Similar to the aforementioned embodiment, each of the DTC patterns 50 is made of the aforementioned alternately stacked four electrode layers 20 and four dielectric layers 32, 34, 36, 38 as the via conductors 46 are distributed on each of the electrode layers 20. Since the structures and fabrication of the electrode layers 20, the dielectric layers 32, 34, 36, 38, and the via conductors 46 are essentially the same as the ones form the aforementioned embodiment, the details of which are not explained herein for the sake of brevity.

Specifically, the DTC patterns 50 include four sets of DTC patterns extending along X-direction or Y-direction, in which the first DTC pattern 52 on top left corner includes a plurality of electrode layers 20 extending along a first direction such as X-direction, the second DTC pattern 54 on top right corner includes a plurality of electrode layers 20 extending along a second direction such as Y-direction, the third DTC pattern 56 on bottom left corner includes a plurality of electrode layers 20 extending along the second direction such as Y-direction, and the fourth DTC pattern 58 on bottom right corner includes a plurality of electrode layers 20 extending along the first direction such as X-direction. In other words, the first DTC pattern 52 and the fourth DTC pattern 58 are disposed diagonally while the second DTC pattern 54 and the third DTC pattern 56 are disposed diagonally. The via conductors 46 are disposed along Y-direction adjacent two sides of the DTC patterns 50 and metal interconnections 40 also extending along Y-direction are disposed on top of the via conductors 46.

In contrast to the four electrode layers 20 from the previous embodiment all have same shape such as all being rectangular under a top view perspective, the electrode layers 20 of this embodiment preferably have different shapes under a top view perspective. As shown on the right portion of FIG. 3, the first electrode layer 22 and the second electrode layer 24 have different shapes in a top view, the second electrode layer 24 and the third electrode layer 26 have different shapes in a top view, and the third electrode layer 26 and the fourth electrode layer 28 have different shapes in a top view, in which the first electrode layer 22 includes a rectangular shape, the second electrode layer 24 includes a T-shape, the third electrode layer 26 includes an irregular U-shape such as a standard U-shape with protruding portions 62 adjacent to two sides of the U-shape, and the fourth electrode layer 28 includes a standard U-shape. The via conductors 46 are disposed on the four electrode layers 20 respectively, including the lower left and right two portions of the first electrode layer 22, the upper central portion of the second electrode layer 24, the two protruding portions 62 of the third electrode layer 26, and the lower central portion of the fourth electrode layer 28. Similar to the aforementioned embodiment, the first electrode layer 22 is disposed under the second electrode layer 24, the second electrode layer 24 is disposed under the third electrode layer 26, and the third electrode layer 26 is disposed under the fourth electrode layer 28.

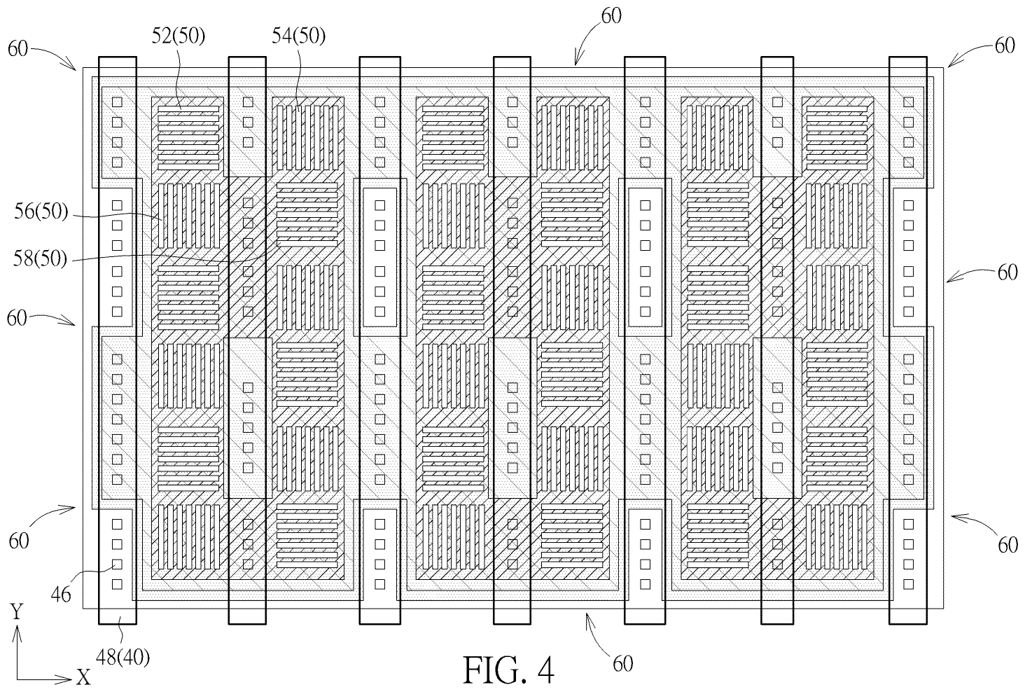

Referring to FIG. 4, FIG. 4 illustrates a layout of an array constituted by grouping a plurality of DTC layout patterns shown in FIG. 2 or FIG. 3. As shown in FIG. 4, in contrast to the DTC layout shown in FIG. 2 or FIG. 3 only includes a single DTC cell 60, the present embodiment preferably connects 9 DTC cells 60 into a 3×3 array, in which each of the DTC cells 60 includes the aforementioned four DTC patterns 50 made of electrode layers 20 extending along X-direction or Y-direction and via conductors 46 only extending along Y-direction adjacent to two sides of the first DTC patterns 52 and third DTC patterns 56 or adjacent to two sides of the second DTC patterns 54 and fourth DTC patterns 58 but not extending along X-direction whatsoever. Moreover, patterns made by metal interconnections 40 are extending along the Y-direction on the via conductors 46 and connected to the via conductors 46 underneath, in which odd column metal interconnections 40 are responsible for transmitting higher voltages while even column metal interconnections 40 are responsible for transmitting lower voltages.

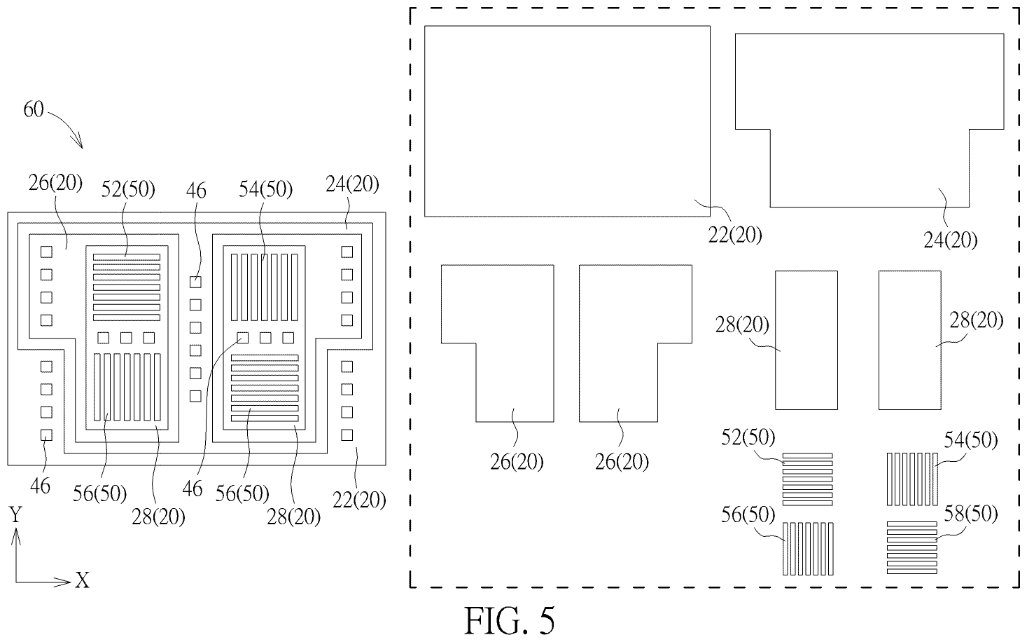

Referring to FIG. 5, FIG. 5 illustrates a perspective view of a DTC and layout thereof, in which the left portion of FIG. 5 illustrates a top view of the DTC layout and the right portion of FIG. 5 illustrates a top view of the four electrode layers 20 from the DTC. As shown in FIG. 5, the DTC layout includes a DTC cell 60 having a plurality of DTC patterns 50 disposed on the substrate 12 and a plurality of via conductors 46 overlapping the DTC cell 60.

Similar to the aforementioned embodiment, each of the DTC patterns 50 is made of the aforementioned alternately stacked four electrode layers 20 and four dielectric layers 32, 34, 36, 38 as the via conductors 46 are distributed on each of the electrode layers 20. Since the structures and fabrication of the electrode layers 20, the dielectric layers 32, 34, 36, 38, and the via conductors 46 are essentially the same as the ones form the aforementioned embodiment, the details of which are not explained herein for the sake of brevity.

Specifically, the DTC patterns 50 of this embodiment also include four sets of DTC patterns extending along X-direction or Y-direction, in which the first DTC pattern 52 on top left corner includes a plurality of electrode layers 20 extending along a first direction such as X-direction, the second DTC pattern 54 on top right corner includes a plurality of electrode layers 20 extending along a second direction such as Y-direction, the third DTC pattern 56 on bottom left corner includes a plurality of electrode layers 20 extending along the second direction such as Y-direction, and the fourth DTC pattern 58 on bottom right corner includes a plurality of electrode layers 20 extending along the first direction such as X-direction. In other words, the first DTC pattern 52 and the fourth DTC pattern 58 are disposed diagonally while the second DTC pattern 54 and the third DTC pattern 56 are disposed diagonally.

In contrast to the via conductors 46 from the previous embodiment only extending along the Y-direction adjacent to two sides of the DTC patterns 50, the via conductors 46 in this embodiment are disposed extending along both the X-direction and Y-direction between the DTC patterns 50 and form a cross-shape under a top view perspective. For instance, a plurality of via conductors 46 are disposed extending along X-direction between the second DTC patterns 54 and the fourth DTC patterns 58 and a plurality of via conductors 46 are disposed extending along Y-direction between the first DTC patterns 52 and second DTC patterns 54.

Moreover, as shown on the right portion of FIG. 5, the first electrode layer 22 and the second electrode layer 24 have different shapes in a top view, the second electrode layer 24 and the third electrode layer 26 have different shapes in a top view, and the third electrode layer 26 and the fourth electrode layer 28 have different shapes in a top view, in which the first electrode layer 22 includes a rectangular shape, the second electrode layer 24 includes a T-shape, the third electrode layer 26 includes two L-shapes, and the fourth electrode layer 28 includes two I-shapes. The via conductors 46 are disposed on the four electrode layers 20 respectively, including the lower left and right portions of the first electrode layer 22, the central portion of the T-shape of the second electrode layer 24, two bottom sides of the L-shape of the third electrode layer 26, and the central portions of the I-shape of the fourth electrode layer 28. Similar to the aforementioned embodiment, the first electrode layer 22 is disposed under the second electrode layer 24, the second electrode layer 24 is disposed under the third electrode layer 26, and the third electrode layer 26 is disposed under the fourth electrode layer 28.

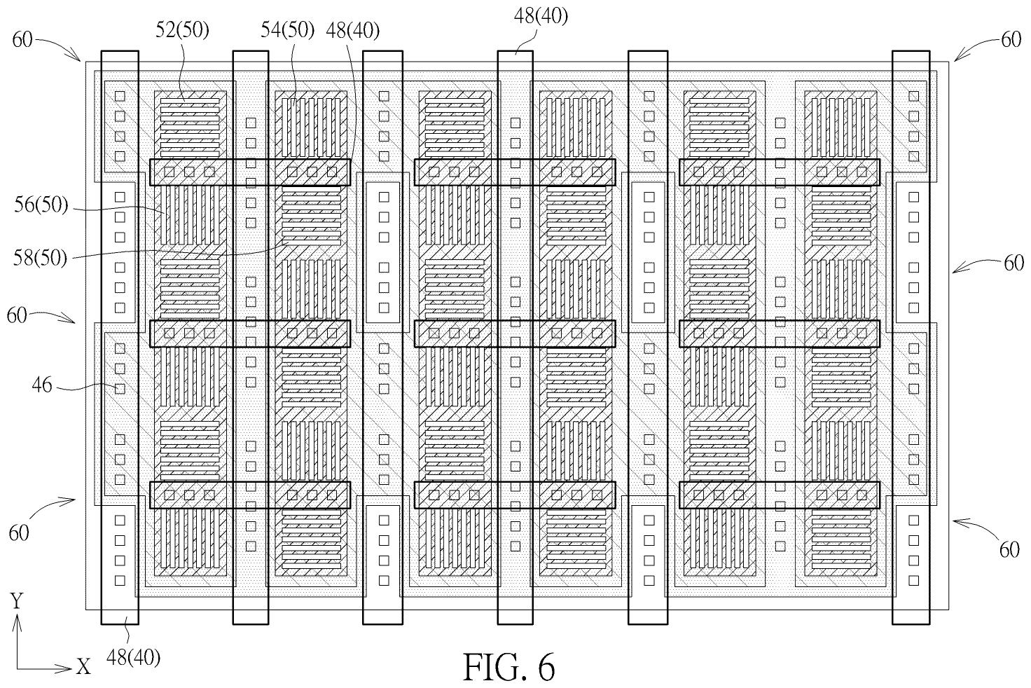

Referring to FIG. 6, FIG. 6 illustrates a layout of an array constituted by grouping a plurality of DTC layout patterns shown in FIG. 5. As shown in FIG. 6, in contrast to the DTC layout shown in FIG. 5 only includes a single DTC cell 60, the present embodiment preferably connects 9 DTC cells 60 into a 3×3 array, in which each of the DTC cells 60 includes the aforementioned four DTC patterns 50 made of electrode layers 20 extending along X-direction or Y-direction and via conductors 46 extending along both X-direction and Y-direction adjacent to two sides of the first DTC patterns 52, second DTC patterns 54, third DTC patterns 56, and fourth DTC patterns 58. Since the via conductors 46 are extending along X-direction and Y-direction at the same time to form a cross shape in a top view, the first level metal interconnections 40 on top of the via conductors 46 are also extending along X-direction and Y-direction while connected to the via conductors 46 underneath. Similar to FIG. 4, odd column metal interconnections 40 are responsible for transmitting higher voltages while even column metal interconnections 40 are responsible for transmitting lower voltages.

Overall, the present invention provides DTC layout with different pattern variations, in which electrode layers from each of the DTC cells could have same shape under top view perspective as shown in FIG. 1 or could have different shapes under top view perspective as shown in FIGS. 3 and 5. By adjusting the shape of the electrode layers 20 as shown in FIGS. 3 and 5 such that the via conductors 46 connected to external circuits could be arranged only extending or spreading along Y-direction (as shown in FIG. 3) or could be arranged in a cross shape arrangement (as shown in FIG. 5), the present invention could lower overall wiring complexity of upper level metal interconnections and reduce overall area of the entire DTC pattern and increase capacitance density when multiple DTC cells 60 are arranged in arrays.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A deep trench capacitor (DTC) layout, comprising:
a first electrode layer on a substrate; and
a second electrode layer on the first electrode layer, wherein the first electrode layer and the second electrode layer comprise different shapes in a top view.

2. The DTC layout of claim 1, further comprising:
a third electrode layer on the second electrode layer, and
a fourth electrode layer on the third electrode layer.

3. The DTC layout of claim 2, wherein the second electrode layer and the third electrode layer comprise different shapes in a top view.

4. The DTC layout of claim 2, wherein the third electrode layer and the fourth electrode layer comprise different shapes in a top view.

5. The DTC layout of claim 2, wherein the fourth electrode layer comprises a U-shape.

6. The DTC layout of claim 1, wherein the first electrode layer comprises a rectangle.

7. The DTC layout of claim 1, wherein the second electrode layer comprises a T-shape.

8. A deep trench capacitor (DTC) layout, comprising:
a DTC cell comprising DTC patterns on a substrate; and
via conductors overlapping the DTC cell, wherein the via conductors comprise a cross shape in a top view.

9. The DTC layout of claim 8, wherein the DTC patterns comprise:
a first DTC pattern comprising first electrode layers extending along a first direction;
a second DTC pattern comprising second electrode layers extending along a second direction;
a third DTC pattern comprising third electrode layers extending along the second direction; and
a fourth DTC pattern comprising fourth electrode layers extending along the first direction.

10. The DTC layout of claim 9, wherein the first DTC pattern and the fourth DTC pattern are disposed diagonally.

11. The DTC layout of claim 9, wherein the second DTC pattern and the third DTC pattern are disposed diagonally.

12. The DTC layout of claim 9, wherein the via conductors comprise:
first via conductors extending along the first direction between the first electrode layers and the third electrode layers.

13. The DTC layout of claim 9, wherein the via conductors comprise:
second via conductors extending along the first direction between the second electrode layers and the fourth electrode layers.

14. The DTC layout of claim 9, wherein the via conductors comprise:
third via conductors extending along the second direction between the first electrode layers and the second electrode layers.
